(19) United States
(12) Patent Application Publication
(10) Pub. No.: US 2026/0143586 A1
(43) Pub. Date: May 21, 2026

(54) WIRING CIRCUIT BOARD

(71) Applicant: NITTO DENKO CORPORATION, Osaka (JP)

(72) Inventors: Tomoaki TANAKA, Osaka (JP); Takashi YAMAMOTO, Osaka (JP); Ryosuke SASAOKA, Osaka (JP)

(73) Assignee: NITTO DENKO CORPORATION, Osaka (JP)

(21) Appl. No.: 19/371,678

(22) Filed: Oct. 28, 2025

(30) Foreign Application Priority Data
Nov. 21, 2024 (JP) 2024-203070

(51) Int. Cl. H05K 1/02

(52) U.S. Cl. CPC H05K 1/0296; H05K 2201/09027

(57) ABSTRACT

A wiring circuit board includes a first part, a second part, and a connecting part connecting the first part and the second part. Furthermore, the wiring circuit board includes a metal layer, a first insulating layer, a first circuit pattern, a second circuit pattern, and a third circuit pattern. The metal layer is disposed continuously in the first part, the second part, and the connecting part. The first circuit pattern is electrically connected to the metal layer of the first part. The second circuit pattern is electrically connected to the metal layer of the second part. The third circuit pattern electrically connects the metal layer of the first part and the metal layer of the second part.

### CROSS-REFERENCE TO RELATED APPLICATION

The present application claims priority from Japanese Patent Application No. 2024-203070 filed on Nov. 21, 2024, the content of which is hereby incorporated by reference into this application.

### TECHNICAL FIELD

The present invention relates to a wiring circuit board.

### BACKGROUND ART

Conventionally, there has been proposed a wiring circuit board including a metal support layer, a conductor layer, and a base insulating layer disposed between the metal support layer and the conductor layer, wherein the conductor layer includes a terminal electrically connected to the metal support layer (for example, see Patent Document 1 below).

### CITATION LIST

### Patent Document

Patent Document 1: Japanese Unexamined Patent Publication No. 2024-122426

### SUMMARY OF THE INVENTION

### Problem to be Solved by the Invention

When the wiring circuit board as described in Patent Document 1 includes a plurality of terminals electrically connected to the metal support layer, reducing the electrical resistance between the terminals is required.

The present invention provides a wiring circuit board capable of reducing the electrical resistance between the circuit patterns (the first circuit pattern and the second circuit pattern) electrically connected to the metal layer.

### Means for Solving the Problem

The present invention [1] includes a wiring circuit board including: a first part, a second part disposed away from the first part, and a connecting part connecting the first part and the second part, wherein the wiring circuit board includes: a metal layer disposed continuously in the first part, the second part, and the connecting part, an insulating layer disposed on a one-side surface of the metal layer in a thickness direction of the metal layer, a first circuit pattern disposed on a one-side surface of the insulating layer of the first part in the thickness direction, and electrically connected to the metal layer of the first part, a second circuit pattern disposed on a one-side surface of the insulating layer of the second part in the thickness direction independently of the first circuit pattern, and electrically connected to the metal layer of the second part, and a third circuit pattern that electrically connects the metal layer of the first part and the metal layer of the second part, or electrically connects the metal layer of the first part and the metal layer of the connecting part.

According to the configuration described above, the third circuit pattern electrically connects the metal layer of the first part and the metal layer of the second part, or electrically connects the metal layer of the first part and the metal layer of the connecting part.

Therefore, in addition to a conductive pathway going through the metal layer of the connecting part, a conductive pathway going through the third circuit pattern is formed between the first circuit pattern and the second circuit pattern.

Consequently, the electrical resistance between the first circuit pattern and the second circuit pattern can be reduced.

The present invention [2] includes the wiring circuit board described in the above-described [1], wherein the first circuit pattern includes a first connected portion connected to the metal layer of the first part; wherein the third circuit pattern includes: a first end portion connected to the metal layer of the first part, and a second end portion connected to the metal layer of the second part or the metal layer of the connecting part; and wherein a distance between the first connected portion of the first circuit pattern and the first end portion of the third circuit pattern is shorter than a distance between the first connected portion of the first circuit pattern and the metal layer of the connecting part.

According to the configuration described above, the conductive pathway going through the third circuit pattern is shorter than the conductive pathway going through the metal layer of the connecting part. In other words, the conductive pathway (the conductive pathway going through the third circuit pattern), which is shorter than the conductive pathway going through the metal layer of the connecting part, is formed between the first circuit pattern and the second circuit pattern.

Therefore, the electrical resistance between the first circuit pattern and the second circuit pattern can reliably be reduced.

The present invention [3] includes the wiring circuit board described in the above-described [2], wherein the second circuit pattern includes a second connected portion connected to the metal layer of the second part; wherein the second end portion of the third circuit pattern is connected to the metal layer of the second part; and wherein a distance between the second connected portion of the second circuit pattern and the second end portion of the third circuit pattern is shorter than a distance between the second connected portion of the second circuit pattern and the metal layer of the connecting part.

According to the configuration described above, the conductive pathway going through the third circuit pattern is even shorter than the conductive pathway going through the metal layer of the connecting part.

Therefore, the electrical resistance between the first circuit pattern and the second circuit pattern can more reliably be reduced.

The present invention [4] includes the wiring circuit board described in any one of the above-described [1] to [3], further including: a fourth circuit pattern disposed on a one-side surface of the insulating layer in the thickness direction independently of the first circuit pattern and the second circuit pattern, and being not electrically connected to the metal layer, wherein the fourth circuit pattern includes: a first terminal disposed in the first part, a second terminal disposed in the second part, and a wire disposed in the first part, the second part, and the connecting part, and electrically connecting the first terminal and the second terminal.

The present invention [5] includes the wiring circuit board described in the above-described [4], wherein the first part includes a first terminal disposition portion in which the first terminal is disposed, and a first wire disposition portion in which a part of the wire is disposed; wherein the second part includes a second terminal disposition portion in which the second terminal is disposed, and a second wire disposition portion in which a part of the wire is disposed; and wherein the third circuit pattern electrically connects the metal layer of the first wire disposition portion and the metal layer of the second wire disposition portion.

The present invention [6] includes the wiring circuit board described in the above-described [4], wherein the first part includes a first terminal disposition portion in which the first terminal is disposed, and a first wire disposition portion in which a part of the wire is disposed; wherein the second part includes a second terminal disposition portion in which the second terminal is disposed, and a second wire disposition portion in which a part of the wire is disposed; and wherein the third circuit pattern electrically connects the metal layer of the first terminal disposition portion and the metal layer of the second terminal disposition portion.

The present invention [7] includes the wiring circuit board described in the above-described [4], wherein the first part includes a first terminal disposition portion in which the first terminal is disposed, and a first wire disposition portion in which a part of the wire is disposed; wherein the second part includes a second terminal disposition portion in which the second terminal is disposed, and a second wire disposition portion in which a part of the wire is disposed; and wherein the third circuit pattern electrically connects the metal layer of the first wire disposition portion and the metal layer of the second terminal disposition portion, or electrically connects the metal layer of the first terminal disposition portion and the metal layer of the second wire disposition portion.

The present invention [8] includes the wiring circuit board described in any one of the above-described [1] to [7], wherein the third circuit pattern is made of the same material as a material of the metal layer.

The present invention [9] includes the wiring circuit board described in any one of the above-described [1] to [7], wherein the third circuit pattern is made of the same material as a material of the first circuit pattern; and wherein the wiring circuit board further includes a support layer made of the same material as a material of the insulating layer, and supporting the third circuit pattern.

The present invention [10] includes the wiring circuit board described in any one of the above-described [1] to [9], wherein the third circuit pattern includes: a first end portion connected to the metal layer of the first part, and a second end portion connected to the metal layer of the second part or the metal layer of the connecting part; and wherein the third circuit pattern has a length greater than a linear distance between the first end portion and the second end portion.

According to the configuration described above, the length of the third circuit pattern is greater than the linear distance between first end portion and the second end portion, and thus the movement of the second part with respect to the first part is allowed.

### Effects of the Invention

According to the wiring circuit board of the present invention, the electrical resistance between the circuit patterns (the first circuit pattern and the second circuit pattern) electrically connected to the metal layer can be reduced.

### BRIEF DESCRIPTION OF THE DRAWINGS

FIG. 1 is a plan view of a wiring circuit board as one embodiment of the present invention (viewed from one side in the thickness direction).

FIG. 2A is a cross-sectional view of the wiring circuit board shown in FIG. 1, taken along line A-A. FIG. 2 B is a cross-sectional view of the wiring circuit board shown in FIG. 1, taken along line B-B.

FIG. 3 is a back view of the wiring circuit board shown in FIG. 1 (viewed from the other side in the thickness direction).

FIG. 4 is a plan view of a wiring circuit board of a modified example (1).

FIG. 5 is a cross-sectional view of the wiring circuit board shown in FIG. 4, taken along line C-C.

FIG. 6 is a plan view of a wiring circuit board of a modified example (2).

FIG. 7 is a back view of the wiring circuit board shown in FIG. 6.

FIG. 8 is a plan view of a wiring circuit board of a modified example (3).

FIG. 9 is a back view of the wiring circuit board shown in FIG. 8.

FIG. 10 is a plan view of a wiring circuit board of a modified example (4).

FIG. 11 is a back view of the wiring circuit board shown in FIG. 10.

FIG. 12 is a plan view of a wiring circuit board of a modified example (5).

FIG. 13 is a back view of the wiring circuit board shown in FIG. 12.

FIG. 14 is a plan view of a wiring circuit board of a modified example (6).

FIG. 15 is a back view of the wiring circuit board shown in FIG. 14.

### DESCRIPTION OF THE EMBODIMENT

### 1. Wiring Circuit Board

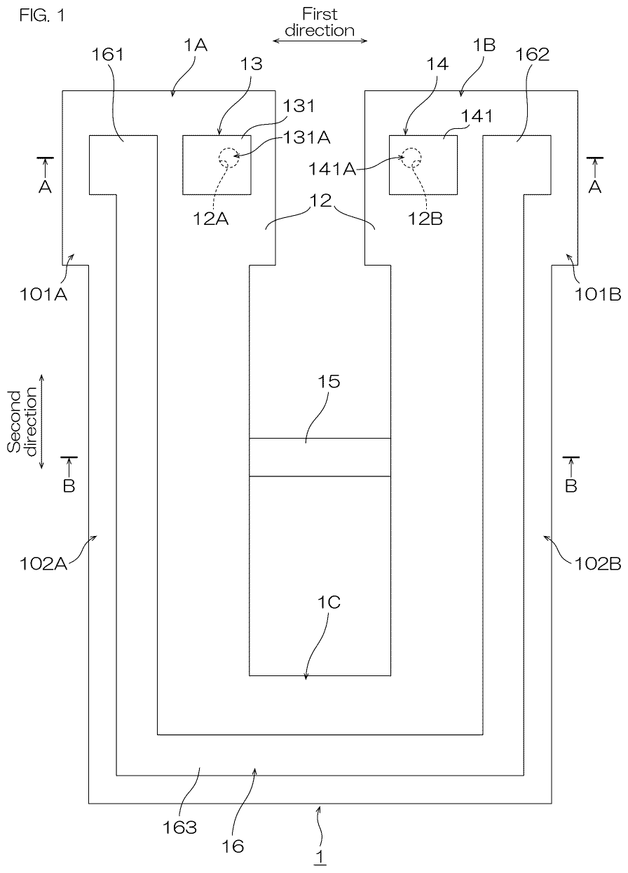

As shown in FIG. 1, a wiring circuit board 1 includes a first part 1A, a second part 1B, and a connecting part 1C.

The first part 1A has a width in a first direction, and extends in a second direction. The second direction is perpendicular to the first direction. The first part 1A has a first terminal disposition portion 101A and a first wire disposition portion 102A. In the first terminal disposition portion 101A, a first terminal 161 described below is disposed. The first terminal disposition portion 101A extends in the first direction and the second direction. The first terminal disposition portion 101A has an approximately rectangular shape. In the first wire disposition portion 102A, a part of a wire 163 described below is disposed. The first wire disposition portion 102A extends from the first terminal disposition portion 101A in the second direction.

The second part 1B is disposed away from the first part 1A in the first direction. The second part 1B has a width in the first direction, and extends in the second direction. The second part 1B has a second terminal disposition portion 101B and a second wire disposition portion 102B. The second terminal disposition portion 101B is disposed away from the first terminal disposition portion 101A in the first direction. In the second terminal disposition portion 101B, a second terminal 162 described below is disposed. The second terminal disposition portion 101B extends in the first direction and the second direction. The second terminal disposition portion 101B has an approximately rectangular shape. The second wire disposition portion 102B is disposed away from the first wire disposition portion 102A in the first direction. In the second wire disposition portion 102B, a part of the wire 163 described below is disposed. The second wire disposition portion 102B extends from the second terminal disposition portion 101B in the second direction.

The connecting part 1C connects the first part 1A and the second part 1B. The connecting part 1C is disposed between the first part 1A and the second part 1B in the first direction. The connecting part 1C has a width in the second direction, and extends in the first direction. One end portion of the connecting part 1C is connected to the first part 1A. The other end portion of the connecting part 1C is connected to the second part 1B.

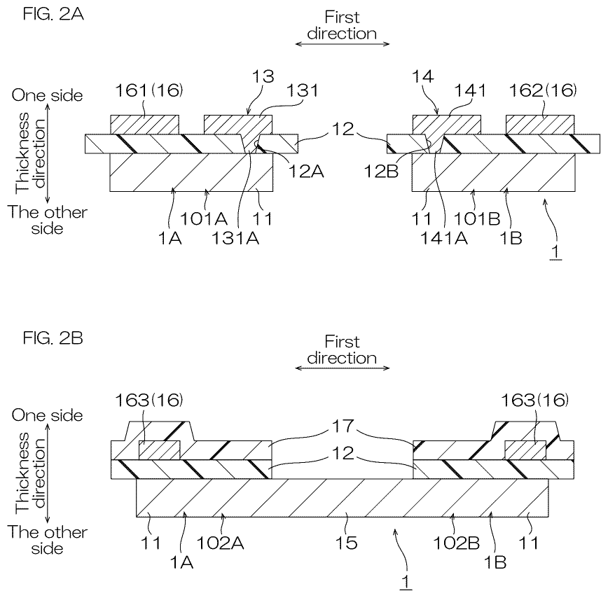

As shown in FIG. 2A and FIG. 2B, the wiring circuit board 1 includes a metal layer 11, a first insulating layer 12 as an example of an insulating layer, a first circuit pattern 13 (see FIG. 1), a second circuit pattern 14 (see FIG. 1), a third circuit pattern 15 (see FIG. 1), a fourth circuit pattern 16 (see FIG. 1), and a second insulating layer 17 (see FIG. 2B).

### (1) Metal Layer

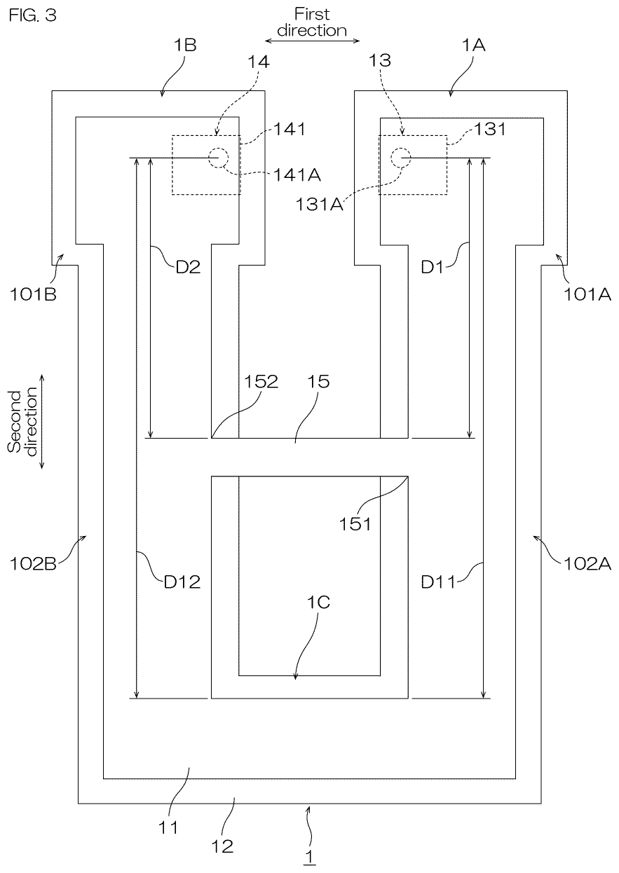

As shown in FIG. 3, the metal layer 11 is disposed continuously in the first part 1A, the second part 1B, and the connecting part 1C. As shown in FIG. 2A and FIG. 2B, the metal layer 11 supports the first insulating layer 12, the first circuit pattern 13, the second circuit pattern 14, the fourth circuit pattern 16, and the second insulating layer 17. Examples of the material of the metal layer 11 includes stainless steel and a copper alloy. The metal layer 11 preferably consists of a copper alloy.

The metal layer 11 may consist of a plurality of layers. For example, the metal layer 11 may include a metal support layer, a conductor layer, and a protective metal layer.

The metal support layer supports the conductor layer and the protective metal layer. The metal support layer is, for example, made of the above-described material of the metal layer 11.

The conductor layer is disposed on a one-side surface of the metal support layer in the thickness direction of the metal layer 11. The conductor layer is disposed between the metal support layer and the protective metal layer in the thickness direction. The conductor layer is made of a metal. Examples of the metal includes copper, silver, gold, iron, aluminum, chromium, and the alloys thereof. The conductor layer is preferably made of copper. The conductor layer is, for example, a plating layer.

The protective metal layer is disposed on a one-side surface of the conductor layer in the thickness direction. The protective metal layer covers the conductor layer. The protective metal layer is disposed between the conductor layer and the first insulating layer 12. The protective metal layer protects the conductor layer. Examples of the material of the protective metal layer includes chromium, nickel, titanium, and the alloys thereof. The protective metal layer preferably consists of chromium. The protective metal layer is, for example, a sputtering layer.

### (2) First Insulating Layer

The first insulating layer 12 is disposed on a one-side surface of the metal layer 11 in the thickness direction of the metal layer 11. The first insulating layer 12 is disposed between the metal layer 11 and the first circuit pattern 13, between the metal layer 11 and the second circuit pattern 14, and between the metal layer 11 and the fourth circuit pattern 16 in the thickness direction. The first insulating layer 12 insulates the metal layer 11 from the first circuit pattern 13, the second circuit pattern 14, and the fourth circuit pattern 16. The first insulating layer 12 is made of resin. Examples of the resin include polyimide, maleimide, epoxy resin, polybenzoxazole, and polyester. The first insulating layer 12 preferably consists of polyimide. The first insulating layer 12 includes a first through hole 12A and a second through hole 12B. The first through hole 12A is disposed in the first part 1A. The second through hole 12B is disposed in the second part 1B.

### (3) First Circuit Pattern

The first circuit pattern 13 is disposed on a one-side surface of the first insulating layer 12 of the first part 1A in the thickness direction. The first circuit pattern 13 includes a terminal 131. In the present embodiment, the first circuit pattern 13 only consists of the terminal 131. The terminal 131 includes a first connected portion 131A. In other words, the first circuit pattern 13 includes the first connected portion 131A. The first connected portion 131A is disposed in the first through hole 12A of the first insulating layer 12. The first connected portion 131A passes through the first through hole 12A, and is connected to the metal layer 11 of the first part 1A. In detail, the first connected portion 131A passes through the first through hole 12A, and is connected to the metal layer 11 of the first terminal disposition portion 101A. In this manner, the first circuit pattern 13 is electrically connected to the metal layer 11 of the first part 1A.

The first circuit pattern 13 may include a wire connected to the terminal 131. In such a case, the wire may include the first connected portion 131A.

Examples of the material of the first circuit pattern 13 include copper, silver, gold, iron, aluminum, chromium, and the alloys thereof. The first circuit pattern 13 preferably consists of copper.

The first circuit pattern 13 may be formed of a plurality of layers. For example, the first circuit pattern 13 may include a protective metal layer and a conductor layer.

The protective metal layer is disposed on the one-side surface of the first insulating layer 12 in the thickness direction. The protective metal layer is disposed between the first insulating layer 12 and the conductor layer of the first circuit pattern 13. The protective metal layer protects the conductor layer of the first circuit pattern 13. Examples of the material of the protective metal layer include chromium, nickel, titanium, and the alloys thereof. The protective metal layer preferably consists of chromium. The protective metal layer is, for example, a sputtering layer.

The conductor layer is disposed on a one-side surface of the protective metal layer in the thickness direction. The conductor layer is, for example, made of the above-described material of the first circuit pattern 13. The conductor layer is, for example, a plating layer.

### (4) Second Circuit Pattern

The second circuit pattern 14 is disposed on a one-side surface of the first insulating layer 12 of the second part 1B in the thickness direction. The second circuit pattern 14 is independent of the first circuit pattern 13. The second circuit pattern 14 includes a terminal 141. In the present embodiment, the second circuit pattern 14 only consists of the terminal 141. The terminal 141 includes a second connected portion 141A. In other words, the second circuit pattern 14 includes the second connected portion 141A. The second connected portion 141A is disposed in the second through hole 12B of the first insulating layer 12. The second connected portion 141A passes through the second through hole 12B, and is connected to the metal layer 11 of the second part 1B. In detail, the second connected portion 141A passes through the second through hole 12B, and is connected to the metal layer 11 of the second terminal disposition portion 101B. In this manner, the second circuit pattern 14 is electrically connected to the metal layer 11 of the second part 1B.

The second circuit pattern 14 may include a wire connected to the terminal 141. In such a case, the wire may include the second connected portion 141A.

The second circuit pattern 14 is, for example, made of the same material of that of the first circuit pattern 13. The second circuit pattern 14 may be made of a plurality of layers in the same manner as the first circuit pattern 13.

### (5) Third Circuit Pattern

As shown in FIG. 3, the third circuit pattern 15 electrically connects the metal layer 11 of the first part 1A and the metal layer 11 of the second part 1B. In this manner, a conductive pathway going through the metal layer 11 of the connecting part 1C and a conductive pathway going through the third circuit pattern 15 are formed between the first circuit pattern 13 and the second circuit pattern 14. Therefore, as compared with a case where only a conductive pathway going through the metal layer 11 of the connecting part 1C is formed between the first circuit pattern 13 and the second circuit pattern 14, the electrical resistance between the first circuit pattern 13 and the second circuit pattern 14 can be reduced.

The third circuit pattern 15 includes a first end portion 151 and a second end portion 152. The first end portion 151 is connected to the metal layer 11 of the first part 1A. The second end portion 152 is connected to the metal layer 11 of the second part 1B. In detail, the third circuit pattern 15 is disposed between the metal layer 11 of the first wire disposition portion 102A and the metal layer 11 of the second wire disposition portion 102B in the first direction. The third circuit pattern 15 is disposed between the connecting part 1C and the first terminal disposition portion 101A in the second direction. The first end portion 151 is connected to the metal layer 11 of the first wire disposition portion 102A. The second end portion 152 is connected to the metal layer 11 of the second wire disposition portion 102B. In this manner, the third circuit pattern 15 electrically connects the metal layer 11 of the first wire disposition portion 102A and the metal layer 11 of the second wire disposition portion 102B.

A distance D1 between the first connected portion 131A of the first circuit pattern 13 and the first end portion 151 of the third circuit pattern 15 is shorter than a distance D11 between the first connected portion 131A of the first circuit pattern 13 and the metal layer 11 of the connecting part 1C.

The distance D1 is shorter than the distance D11, and thus the conductive pathway going through the third circuit pattern 15 is shorter than the conductive pathway going through the metal layer 11 of the connecting part 1C. That is, the conductive pathway (the conductive pathway going through the third circuit pattern 15), which is shorter than the conductive pathway going through the metal layer 11 of the connecting part 1C, is formed between the first circuit pattern 13 and the second circuit pattern 14. Therefore, the electrical resistance between the first circuit pattern 13 and the second circuit pattern 14 can reliably be reduced.

A distance D2 between the second connected portion 141A of the second circuit pattern 14 and the second end portion 152 of the third circuit pattern 15 is shorter than a distance D12 between the second connected portion 141A of the second circuit pattern 14 and the metal layer 11 of the connecting part 1C.

The distance D1 is shorter than the distance D11, and the distance D2 is shorter than the distance D12. Thus, the conductive pathway going through the third circuit pattern 15 is even shorter than the conductive pathway going through the metal layer 11 of the connecting part 1C. Therefore, the electrical resistance between the first circuit pattern 13 and the second circuit pattern 14 can more reliably be reduced.

In the present embodiment, the third circuit pattern 15 is made of the same material as that of the metal layer 11, and continuous to the metal layer 11.

### (6) Fourth Circuit Pattern

As shown in FIG. 2A and FIG. 2B, the fourth circuit pattern 16 is disposed on the one-side surface of the first insulating layer 12 in the thickness direction. The fourth circuit pattern 16 is independent of the first circuit pattern 13 and the second circuit pattern 14. The fourth circuit pattern 16 is not electrically connected to the metal layer 11. The fourth circuit pattern 16 is, for example, made of the same material as that of the first circuit pattern 13. The fourth circuit pattern 16 may be made of a plurality of layers in the same manner as the first circuit pattern 13.

As shown in FIG. 1, the fourth circuit pattern 16 includes the first terminal 161, the second terminal 162, and the wire 163.

The first terminal 161 is disposed in the first part 1A. In detail, the first terminal 161 is disposed in the first terminal disposition portion 101A. The first terminal 161 is disposed away from the first circuit pattern 13.

The second terminal 162 is disposed in the second part 1B. In detail, the second terminal 162 is disposed in the second terminal disposition portion 101B. The second terminal 162 is disposed away from the second circuit pattern 14.

The wire 163 electrically connects the first terminal 161 and the second terminal 162. The wire 163 is disposed in the first part 1A, the second part 1B, and the connecting part 1C.

### (7) Second Insulating Layer

As shown in FIG. 2B, the second insulating layer 17 is disposed on the one-side surface of the first insulating layer 12 in the thickness direction. The second insulating layer 17 is made of resin. Examples of the resin include polyimide, maleimide, epoxy resin, polybenzoxazole, and polyester. The second insulating layer 17 covers the wire 163. The second insulating layer 17 does not cover at least a part of each of the terminal 131, the terminal 141, the first terminal 161, and the second terminal 162.

### 2. Operations and Effects

(1) According to the wiring circuit board 1, as shown in FIG. 3, the third circuit pattern 15 electrically connects the metal layer 11 of the first part 1A and the metal layer 11 of the second part 1B.

Therefore, the conductive pathway going through the metal layer 11 of the connecting part 1C and the conductive pathway going through the third circuit pattern 15 are formed between the first circuit pattern 13 and the second circuit pattern 14.

Consequently, as compared with a case where only a conductive pathway going through the metal layer 11 of the connecting part 1C is formed between the first circuit pattern 13 and the second circuit pattern 14, the electrical resistance between the first circuit pattern 13 and the second circuit pattern 14 can be reduced.

(2) According to the wiring circuit board 1, as shown in FIG. 3, the distance D1 between the first connected portion 131A of the first circuit pattern 13 and the first end portion 151 of the third circuit pattern 15 is shorter than the distance D11 between the first connected portion 131A of the first circuit pattern 13 and the metal layer 11 of the connecting part 1C.

Therefore, the conductive pathway going through the third circuit pattern 15 is shorter than the conductive pathway going through the metal layer 11 of the connecting part 1C. That is, the conductive pathway (the conductive pathway going through the third circuit pattern 15) , which is shorter than the conductive pathway going through the metal layer 11 of the connecting part 1C, is formed between the first circuit pattern 13 and the second circuit pattern 14.

Consequently, the electrical resistance between the first circuit pattern 13 and the second circuit pattern 14 can reliably be reduced.

(3) According to the wiring circuit board 1, as shown in FIG. 3, the distance D2 between the second connected portion 141A of the second circuit pattern 14 and the second end portion 152 of the third circuit pattern 15 is shorter than the distance D12 between the second connected portion 141A of the second circuit pattern 14 and the metal layer 11 of the connecting part 1C.

Therefore, the conductive pathway going through the third circuit pattern 15 is even shorter than the conductive pathway going through the metal layer 11 of the connecting part 1C.

Consequently, the electrical resistance between the first circuit pattern 13 and the second circuit pattern 14 can more reliably be reduced.

### 3. Modified Examples

Modified examples are described. In the modified examples, the same members as in the above-described embodiment are given the same numerical references and the descriptions thereof are omitted.

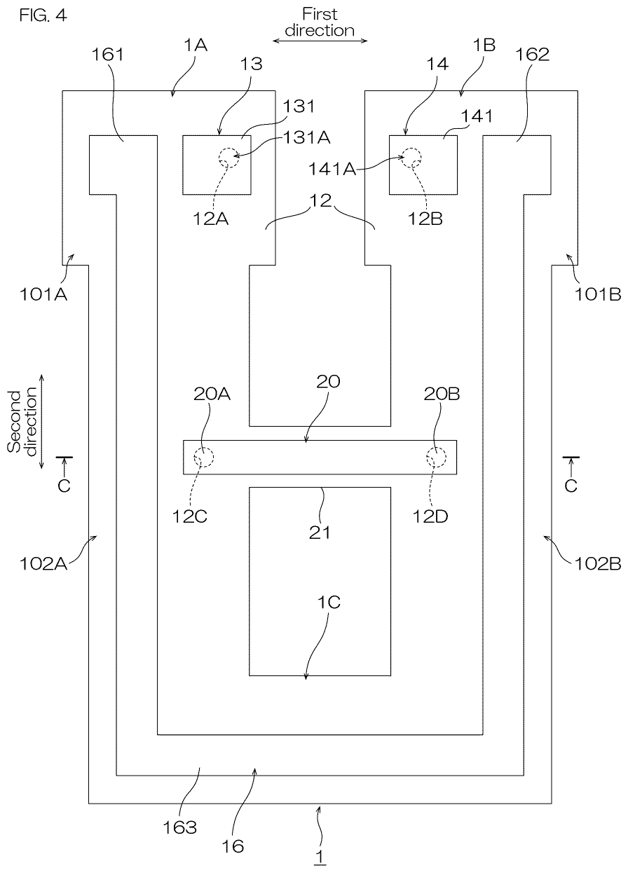

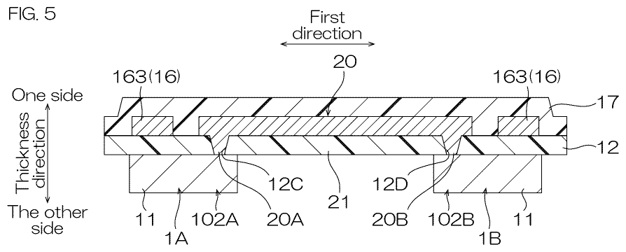

(1) As shown in FIG. 4 and FIG. 5, a third circuit pattern 20 may be made of the same material as that of the first circuit pattern 13. In such a case, the first insulating layer 12 includes a third through hole 12C and a fourth through hole 12D. The third through hole 12C is disposed in the first wire disposition portion 102A of the first part 1A. The fourth through hole 12D is disposed in the second wire disposition portion 102B of the second part 1B. The third circuit pattern 20 includes a third connected portion 20A and a fourth connected portion 20B.

The third connected portion 20A is disposed in the third through hole 12C of the first insulating layer 12. The third connected portion 20A passes through the third through hole 12C, and is connected to the metal layer 11 of the first wire disposition portion 102A. In this manner, the third circuit pattern 20 is electrically connected to the metal layer 11 of the first part 1A.

The fourth connected portion 20B is disposed in the fourth through hole 12D of the first insulating layer 12. The fourth connected portion 20B passes through the fourth through hole 12D, and is connected to the metal layer 11 of the second wire disposition portion 102B. In this manner, the third circuit pattern 20 is electrically connected to the metal layer 11 of the second part 1B.

Furthermore, the wiring circuit board 1 may further include a support layer 21. The third circuit pattern 20 is disposed on a one-side surface of the support layer 21 in the thickness direction. In this manner, the support layer 21 supports the third circuit pattern 20. The support layer 21 is made of the same material as that of the first insulating layer 12, and is continue to the first insulating layer 12.

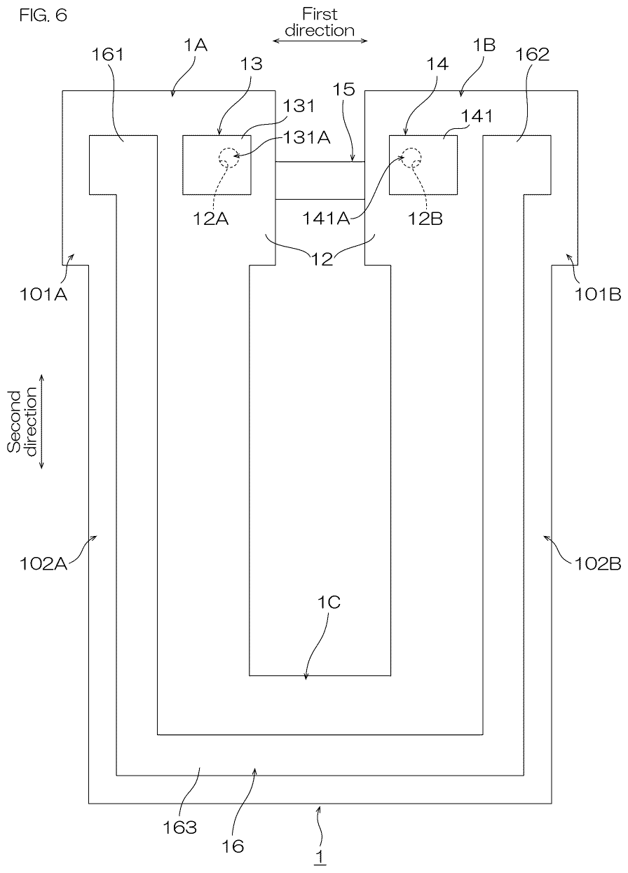

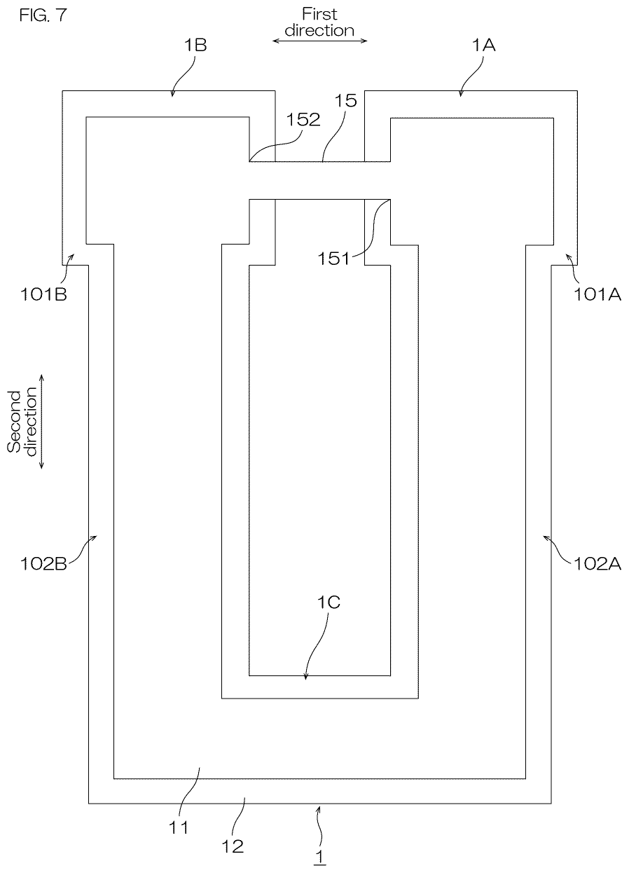

(2) As shown in FIG. 6 and FIG. 7, the third circuit pattern 15 may electrically connect the metal layer 11 of the first terminal disposition portion 101A and the metal layer 11 of the second terminal disposition portion 101B.

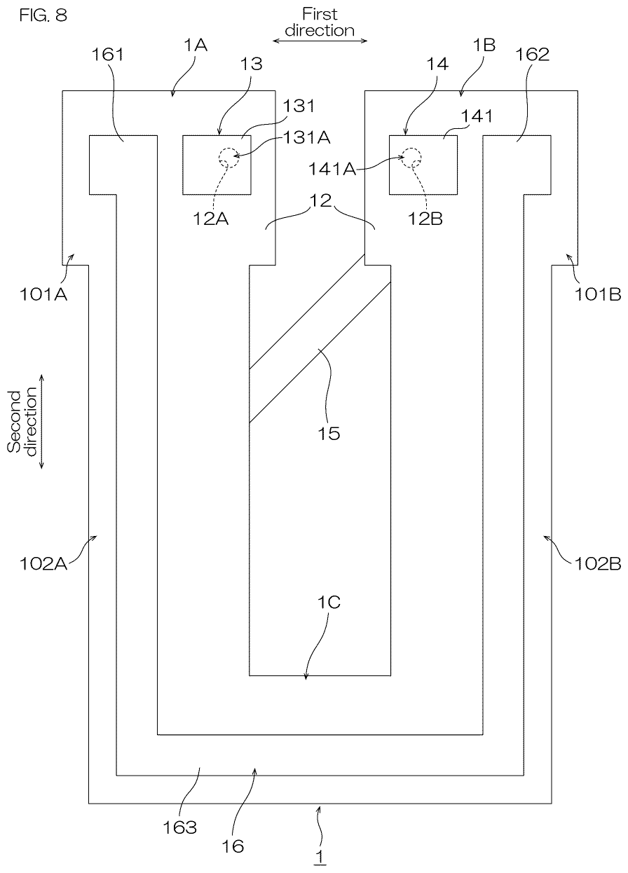

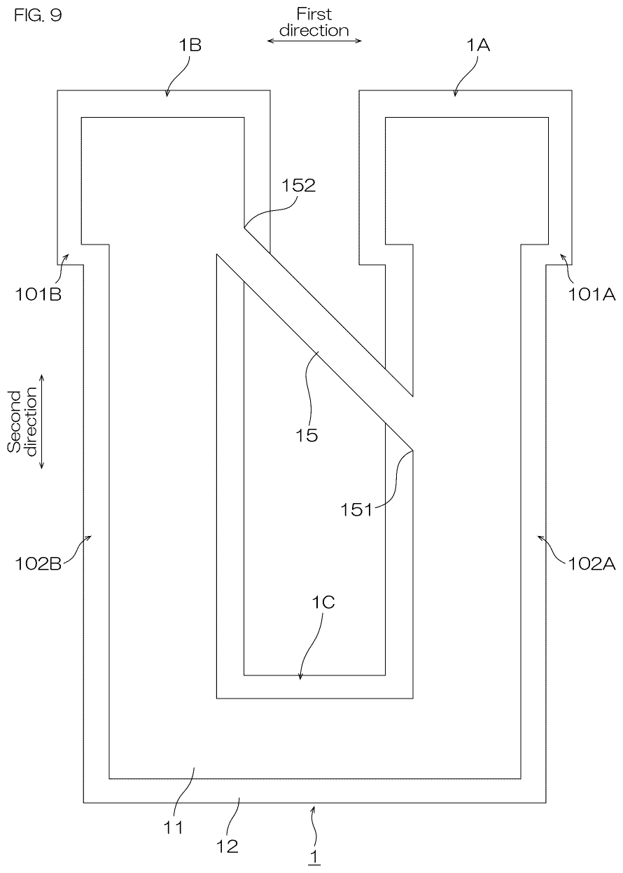

(3) As shown in FIG. 8 and FIG. 9, the third circuit pattern 15 may electrically connect the metal layer 11 of the first wire disposition portion 102A and the metal layer 11 of the second terminal disposition portion 101B.

Although not shown, the third circuit pattern 15 may electrically connect the metal layer 11 of the first terminal disposition portion 101A and the metal layer 11 of the second wire disposition portion 102B.

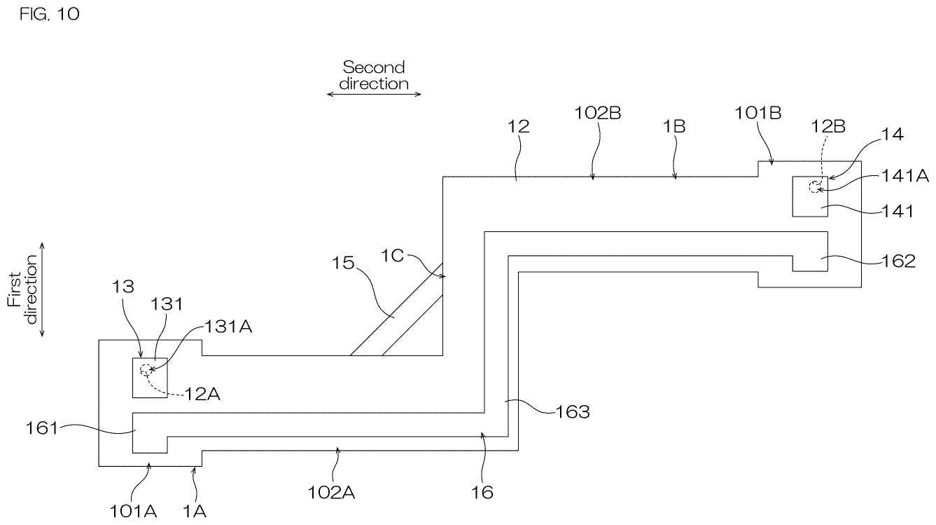

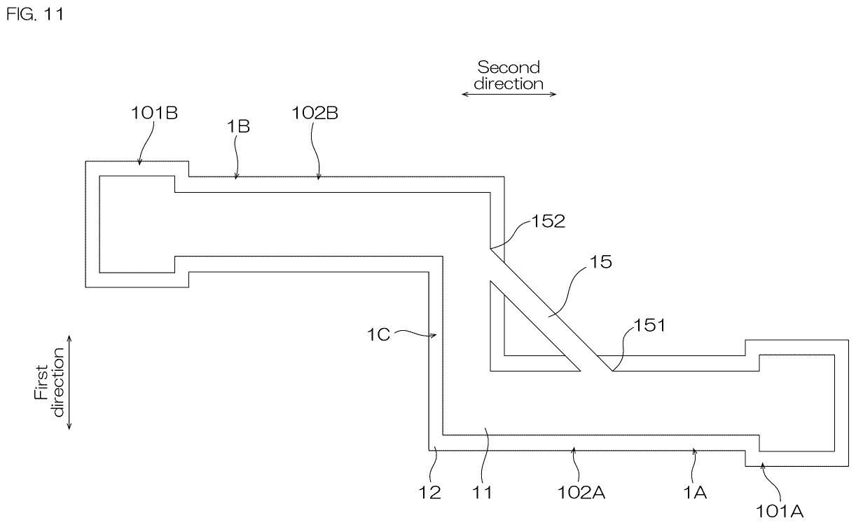

(4) As shown in FIG. 10 and FIG. 11, the second part 1B may be disposed on a side opposite to the first part 1A with respect to the connecting part 1C in the second direction. In other words, the connecting part 1C may be disposed between the first part 1A and the second part 1B in the second direction.

The third circuit pattern 15 may electrically connect the metal layer 11 of the first part 1A and the metal layer 11 of the connecting part 1C. In detail, the first end portion 151 of the third circuit pattern 15 may be connected to the metal layer 11 of the first part 1A, and the second end portion 152 of the third circuit pattern 15 may be connected to the metal layer 11 of the connecting part 1C.

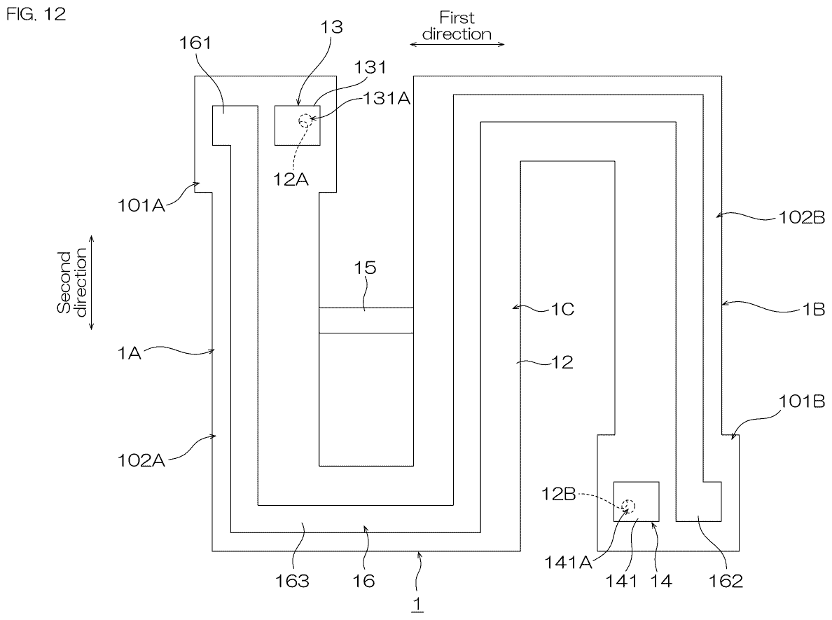

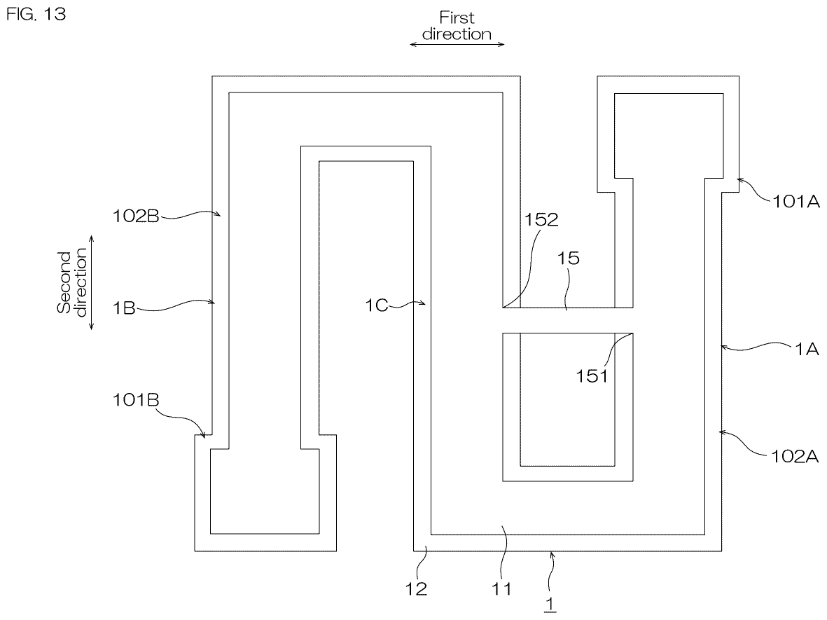

(5) As shown in FIG. 12 and FIG. 13, the connecting part 1C may be disposed between the first part 1A and the second part 1B in the first direction. The wiring circuit board 1 has an S shape in the plan view. In such a case, in the same manner as in the above-described modified example (4), the third circuit pattern 15 may electrically connect the metal layer 11 of the first part 1A and the metal layer 11 of the connecting part 1C. In detail, the first end portion 151 of the third circuit pattern 15 may be connected to the metal layer 11 of the first part 1A, and the second end portion 152 of the third circuit pattern 15 may be connected to the metal layer 11 of the connecting part 1C.

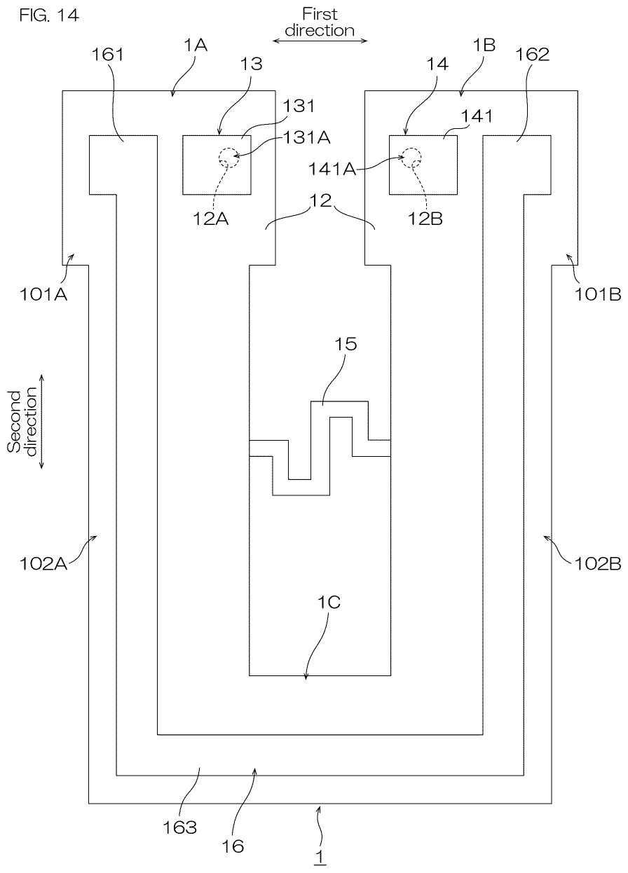

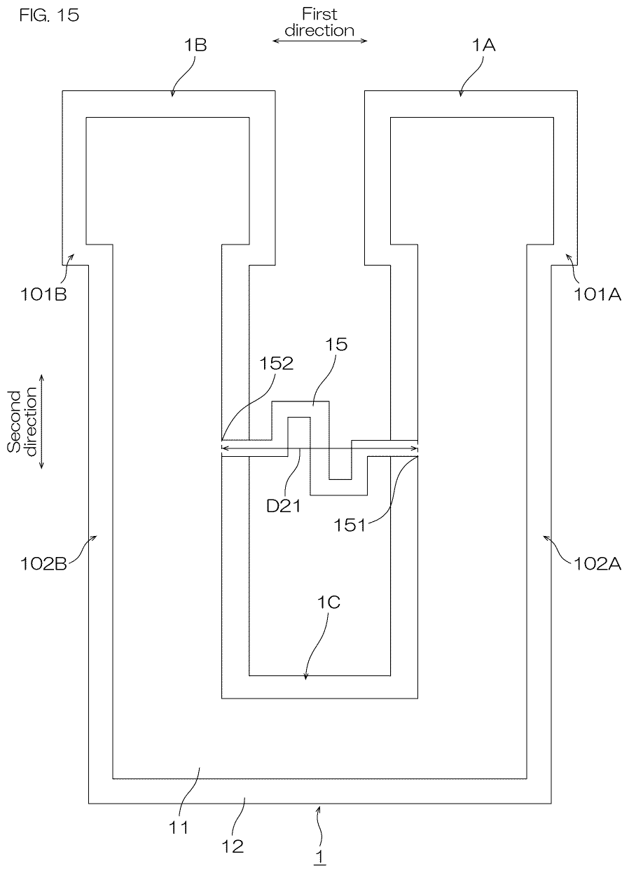

(6) As shown in FIG. 14 and FIG. 15, the length of the third circuit pattern 15 is greater than a linear distance D21 between the first end portion 151 and the second end portion 152. When the length of the third circuit pattern 15 is greater than the linear distance D21 between the first end portion 151 and the second end portion 152, the movement of the second part 1B with respect to the first part 1A can be allowed.

(7) In the above-described modified examples (1) to (6), the same operations and effects as in the above-described embodiment can be obtained.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The wiring circuit board of the present invention can be used for connecting electronic components.

### DESCRIPTION OF REFERENCE NUMERALS

1 Wiring circuit board
1A First part
101A First terminal disposition portion
102A First wire disposition portion
1B Second part
101B Second terminal disposition portion
102B Second wire disposition portion
1C Connecting part
11 Metal layer
12 First insulating layer
13 First circuit pattern
131A First connected portion
14 Second circuit pattern
141A Second connected portion
15 Third circuit pattern
151 First end portion
152 Second end portion
16 Fourth circuit pattern
161 First terminal
162 Second terminal
163 Wire
21 Support layer
D1 Distance between the first connected portion and the first end portion
D2 Distance between the second connected portion and the second end portion
D11 Distance between the first connected portion and the metal layer of the connecting part
D12 Distance between the second connected portion and the metal layer of the connecting part
D21 Linear distance between the first end portion and the second end portion

1. A wiring circuit board comprising: a first part, a second part disposed away from the first part, and a connecting part connecting the first part and the second part,
wherein the wiring circuit board includes:
a metal layer disposed continuously in the first part, the second part, and the connecting part,
an insulating layer disposed on a one-side surface of the metal layer in a thickness direction of the metal layer,
a first circuit pattern disposed on a one-side surface of the insulating layer of the first part in the thickness direction, and electrically connected to the metal layer of the first part,
a second circuit pattern disposed on a one-side surface of the insulating layer of the second part in the thickness direction independently of the first circuit pattern, and electrically connected to the metal layer of the second part, and
a third circuit pattern that electrically connects the metal layer of the first part and the metal layer of the second part, or electrically connects the metal layer of the first part and the metal layer of the connecting part.

2. The wiring circuit board according to claim 1,
wherein the first circuit pattern includes a first connected portion connected to the metal layer of the first part;
wherein the third circuit pattern includes:
a first end portion connected to the metal layer of the first part, and
a second end portion connected to the metal layer of the second part or the metal layer of the connecting part; and
wherein a distance between the first connected portion of the first circuit pattern and the first end portion of the third circuit pattern is shorter than a distance between the first connected portion of the first circuit pattern and the metal layer of the connecting part.

3. The wiring circuit board according to claim 2,
wherein the second circuit pattern includes a second connected portion connected to the metal layer of the second part;
wherein the second end portion of the third circuit pattern is connected to the metal layer of the second part; and
wherein a distance between the second connected portion of the second circuit pattern and the second end portion of the third circuit pattern is shorter than a distance between the second connected portion of the second circuit pattern and the metal layer of the connecting part.

4. The wiring circuit board according to claim 1, further comprising:
a fourth circuit pattern disposed on a one-side surface of the insulating layer in the thickness direction independently of the first circuit pattern and the second circuit pattern, and being not electrically connected to the metal layer,
wherein the fourth circuit pattern includes:
a first terminal disposed in the first part,
a second terminal disposed in the second part, and
a wire disposed in the first part, the second part, and the connecting part, and electrically connecting the first terminal and the second terminal.

5. The wiring circuit board according to claim 4,
wherein the first part includes a first terminal disposition portion in which the first terminal is disposed, and a first wire disposition portion in which a part of the wire is disposed;
wherein the second part includes a second terminal disposition portion in which the second terminal is disposed, and a second wire disposition portion in which a part of the wire is disposed; and
wherein the third circuit pattern electrically connects the metal layer of the first wire disposition portion and the metal layer of the second wire disposition portion.

6. The wiring circuit board according to claim 4,
wherein the first part includes a first terminal disposition portion in which the first terminal is disposed, and a first wire disposition portion in which a part of the wire is disposed;
wherein the second part includes a second terminal disposition portion in which the second terminal is disposed, and a second wire disposition portion in which a part of the wire is disposed; and
wherein the third circuit pattern electrically connects the metal layer of the first terminal disposition portion and the metal layer of the second terminal disposition portion.

7. The wiring circuit board according to claim 4,
wherein the first part includes a first terminal disposition portion in which the first terminal is disposed, and a first wire disposition portion in which a part of the wire is disposed;
wherein the second part includes a second terminal disposition portion in which the second terminal is disposed, and a second wire disposition portion in which a part of the wire is disposed; and
wherein the third circuit pattern electrically connects the metal layer of the first wire disposition portion and the metal layer of the second terminal disposition portion, or electrically connects the metal layer of the first terminal disposition portion and the metal layer of the second wire disposition portion.

8. The wiring circuit board according to claim 1,
wherein the third circuit pattern is made of the same material as a material of the metal layer.

9. The wiring circuit board according to claim 1,
wherein the third circuit pattern is made of the same material as a material of the first circuit pattern; and
wherein the wiring circuit board further includes a support layer made of the same material as a material of the insulating layer, and supporting the third circuit pattern.

10. The wiring circuit board according to claim 1,
wherein the third circuit pattern includes:
a first end portion connected to the metal layer of the first part, and
a second end portion connected to the metal layer of the second part or the metal layer of the connecting part; and
wherein the third circuit pattern has a length greater than a linear distance between the first end portion and the second end portion.
